(19) United States
(12) Patent Application Publication
(10) Pub. No.: US 2003/0114028 A1
(43) Pub. Date: Jun. 19, 2003

(54) Solder-bearing lead

(76) Inventors: Masao Ohkita, Tu-Chen (TW); Hsiu-Yuan Hsu, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/017,121

(22) Filed: Dec. 14, 2001

(51) Int. Cl. H05K 1/00

(52) U.S. Cl. 439/83

(57) ABSTRACT

An electrical connector (4) includes an insulative housing (40), a number of leads (5) and a number of solders (7) attached to the leads. The insulative housing has a mating face (41), a mounting face (42) and a number of passageways (43) extending through the mating face and the mounting face. The leads are received in the passageways and each includes a contacting portion (50) exposed to the mating face and a solder portion (52) connected to the contacting portion and exposed to the mounting face. The solder portion defines a hole (54) extending therethrough and the solder extends through the hole and is revited to the solder portion.

### BACKGROUND OF THE INVENTION

1. Field of the Invention

The present invention relates to a solder-bearing lead for attachment to a substrate or integrated circuit chip or other circuit device, having a discrete mass of solder mechanically held by the lead in position to be melted for electrically and mechanically connecting to the circuit device.

2. Description of the Related Art

Various means have been previously provided where a quantity of solder is associated with a lead so that when the lead is juxtaposed to a substrate (usually with a corresponding conductive surface area or pad with which the lead is to be connected), and the assembly is heated, the molten solder covers the Juxtaposed lead and substrate to form, when cool, a soldered joint serving as an electrical and mechanical connection between the lead and the substrate.

Referring to FIG. 11, one type of conventional lead 2 is schematically shown received, in ways known to persons skilled in the pertinent art, in a corresponding passageway 13 of an insulative housing 10 to constitute an electrical connector 1 for being mounted to a circuit device 30. The insulative housing 10 defines a mating face 11 and a mounting face 12. The lead 2 comprises a contacting portion 20 exposed to the mating face 11 of the insulative housing 10 for electrically and mechanically connecting with a complementary electrical element (not shown) and a solder portion 21 exposed to the mounting face 12 of the insulative housing 10. A solder ball 23 is attached to a bottom 22 of the solder portion 21 to, after melting, electrically and mechanically connect the lead 2 with a conductive pad 31 of the circuit device 30.

The solder ball 23 is attached to the bottom 22 of the solder portion 21 only by the metallurgical bond therebetween, so the solder ball 23 is apt to fall off from the lead 2, thereby interrupting electrical and mechanical connection between the lead 2 and the conductive pad 31 of the circuit device 30.

Furthermore, a mass of flux is often applied to surfaces of the bottom 22 of the lead 2 and of the conductive pad 31 of the circuit device 30 to assist flowing of the solder fluid. The flux is apt to be applied through error to an unwanted portion, for example, the contacting portion 20 of the lead 2, to cause the dilution of the contacting portion 20 by the solder, thereby adversely affecting the electrical connection between the contacting portion 20 and the complementary electrical element.

Therefore, an improved solder-bearing lead is desired to overcome the disadvantages of the prior art.

### SUMMARY OF THE INVENTION

A first object of the present invention is to provide a lead which reliably secures a discrete mass of solder thereon.

A second object of the present invention is to provide a solder-bearing lead which ensures a reliable electrical connection between the lead and a printed circuit board or a complementary electrical element.

An electrical connector in accordance with the present invention comprises an insulative housing and a plurality of solder-bearing leads received in the insulative housing. The solder-bearing leads each have a lead comprising a contacting portion and a solder portion, and a discrete mass of solder. The solder portion defines a hole extending therethrough and the solder extends through the hole and is rivetedly secured to the solder portion.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a partially cutaway perspective view of an electrical connector comprising a schematic lead in accordance with a first embodiment of the present invention;

FIG. 2 is a cross-sectional view taken from line 2-2 of FIG. 1 and further showing a solder and a circuit device;

FIG. 3 is a schematic view of a lead of the electrical connector of FIG.

FIG. 4 is a schematic view of a lead in accordance with a second embodiment of the present invention;

FIG. 5 is a schematic view of a lead in accordance with a third embodiment of the present invention;

FIG. 6 is a view similar to FIG. 3 but the solder in the form of wire or rod is shown without securing to the lead;

FIG. 7 is a cross-sectional view of FIG. 6;

FIG. 8 is a view similar to FIG. 7 but the solder in the form of wire or rod has been inserted through a hole of the lead and a pair of shaping blocks are shown at an upper and a lower sides of the solder, respectively;

FIG. 9 is a view similar to FIG. 7 but the solder has been riveted by the shaping blocks and mechanically secured to the lead;

FIG. 10 is a view similar to FIG. 9 but a mass of flux has been included in the solder in accordance with a fourth embodiment of the present invention; and

FIG. 11 is a partial perspective view of an electrical connector having schematic conventional solder-bearing leads therein.

### DETAILED DESCRIPTION OF THE INVENTION

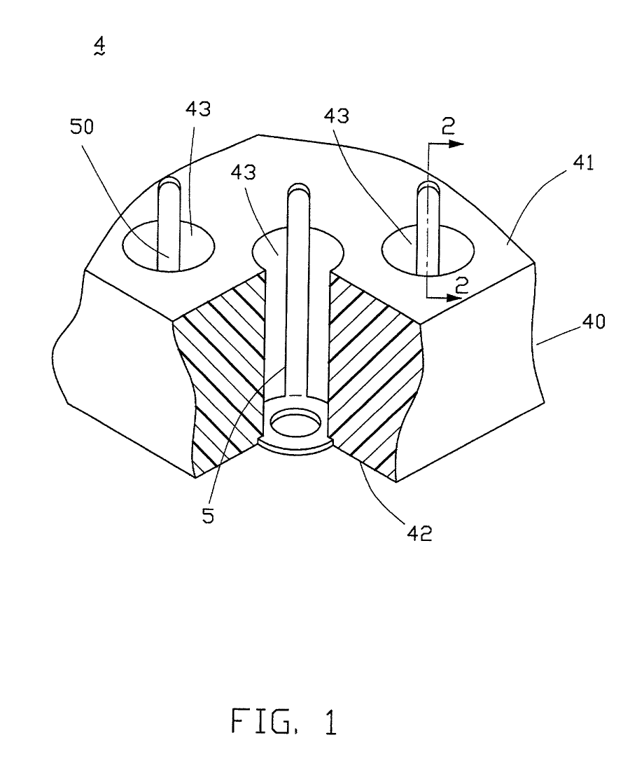

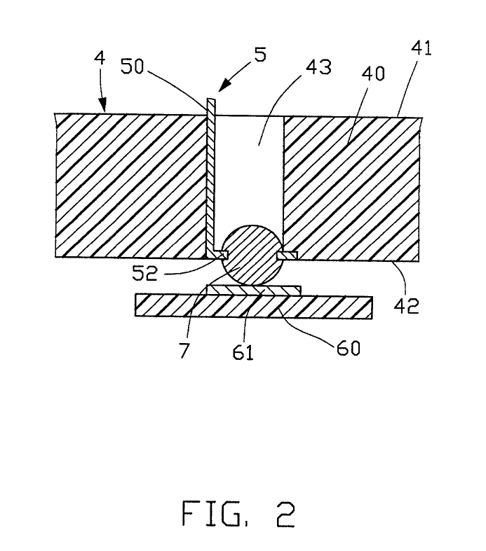

Referring to FIGS. 1 and 2, an electrical connector 4 comprises an insulative housing 40 defining a mating face 41 and a mounting face 42 and a plurality of passageways 43 extending through the mating and the mounting faces 41, 42, a plurality of leads 5 in accordance with a first embodiment of the present invention received, in ways known to one of ordinary skill in the pertinent art, in the passageways 43 of the insulative housing 40, and a discrete mass of solder 7 secured to each lead 5.

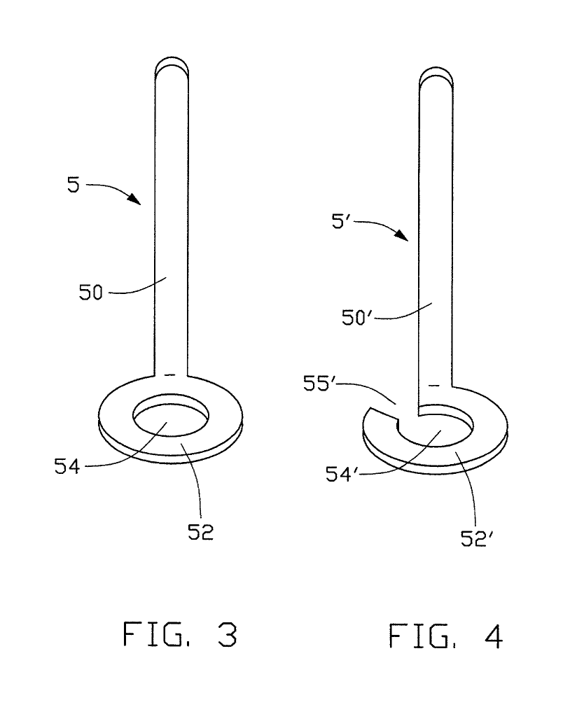

Referring also to FIG. 3, each lead 5 is schematically shown and comprises a contacting portion 50 exposed to the mating face 41 of the insulative housing 40 for electrically connecting with a complementary electrical element (not shown) and a solder portion 52 connected to the contacting portion 50 and exposed to the mounting face 42 of the insulative housing 40. The solder portion 52 defines a hole 54 in a center thereof extending through a top and a bottom surfaces thereof.

Referring to FIG. 4, a solder portion 52′ of a lead 5′, in accordance with a second embodiment of the present invention and schematically shown, defines not only a hole 54′ in a center thereof and extending through an upper and a lower surfaces thereof, but also a channel 55′ at a peripheral portion of the hole 54′ to expose the hole 54′ outwardly.

Referring to FIG. 5, a contacting portion 50″ of a lead 5″, in accordance with a third embodiment of the present invention and schematically shown, comprises a pair of opposite beams 56″ connecting with a periphery of a solder portion 52″ of the lead 5″.

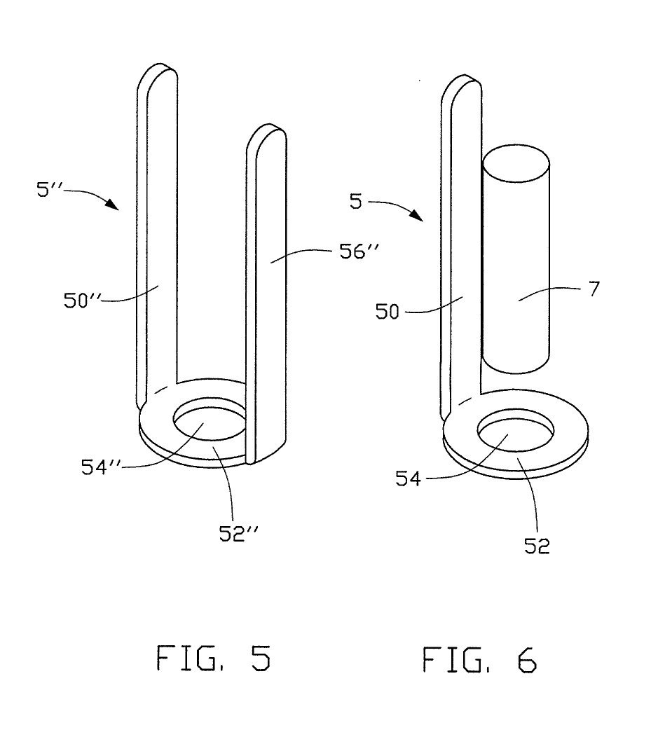

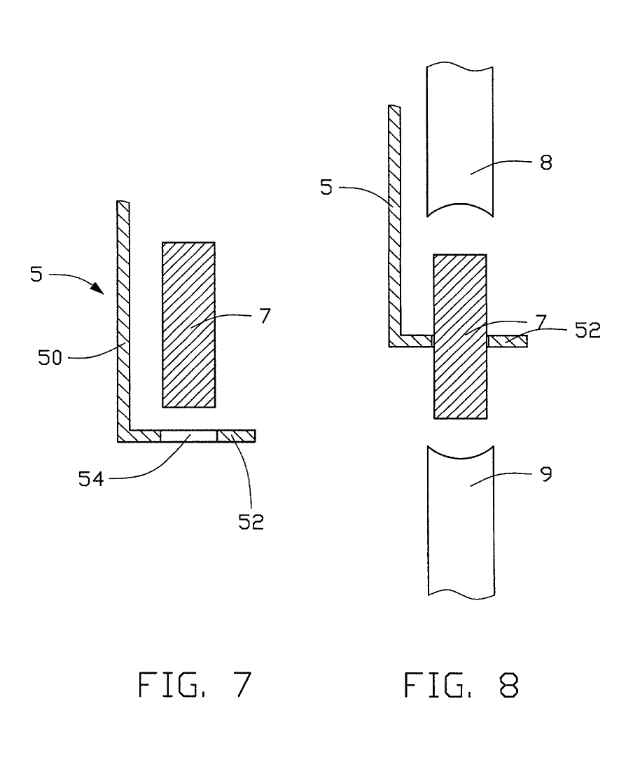

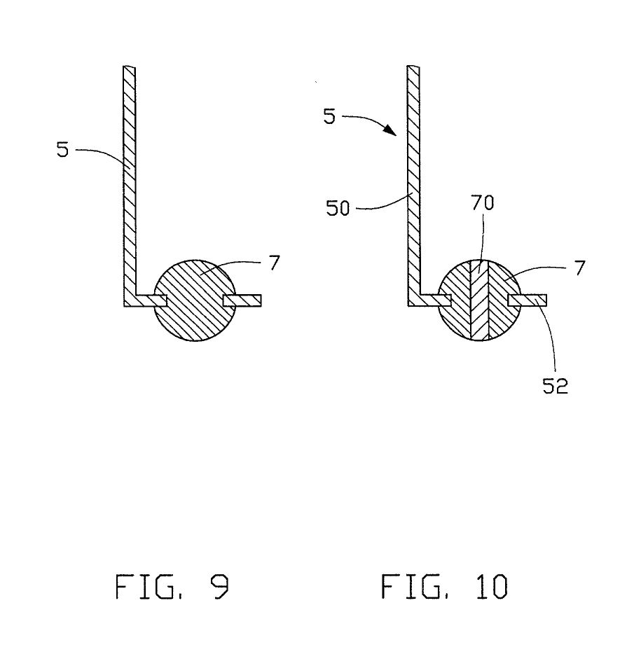

Referring to FIGS. 6-9, a process of securing a discrete mass of solder to the lead is shown. Since the processes for securing the solders to the leads 5, 5′ and 5″ are similar, only the process for the lead 5 is described herein. Referring to FIGS. 6 and 7, a discrete mass of solder 7 in the form of wire or rod is firstly vertically aligned with the hole 54 of the lead 5. Then the solder 7 in the form of wire or rod is inserted into the hole 54 as shown in FIG. 8 and is preferably transferred by an automatic machine (not shown) to be located between an upper and a lower shaping blocks 8, 9. The upper and the lower shaping blocks 8, 9 sandwich therebetween the solder portion 52 of the lead 5 with the solder 7 in the form of wire or rod thereon and compress against the solder 7 in the form of wire or rod to shape the solder 7 into a solder ball. As is clearly shown in FIG. 9, portions of the solder 7 beyond the upper and the bottom surfaces of the solder portion 52 have been so riveted as to have dimension larger than the diameter of the hole 54, thereby reliably securing the solder 7 to the lead 5.

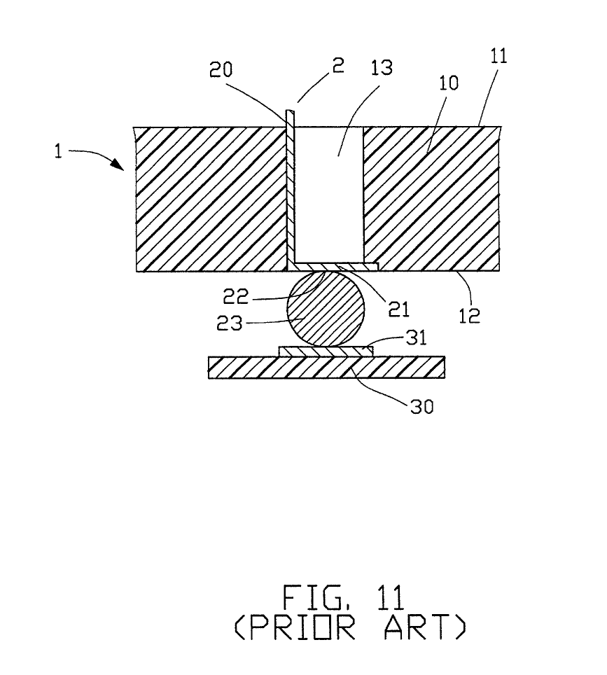

Referring also to FIG. 10, a mass of flux 70, in accordance with a fourth embodiment of the present invention, is included in the solder wire or rod 7 as manufactured instead of, as is in conventional cases, adding to the solder portion 52 of the lead 5.

Since the solder 7 is firstly mechanically secured to the solder portion of the lead, the possibility of the solder falling off the lead is reduced and the connection between the solder and the lead is ensured. In addition, mechanically riveting the solder to the lead is easy to achieve using automatic machines, thereby simplifying the forming process and reducing the cost thereof. Furthermore, the solder could be formed into any desired shapes and any desired heights by adjusting the shaping blocks. Therefore, coplanarity of solders of an electrical connector can be ensured. Furthermore, adding the flux to the solder instead of to the lead eliminates or reduces the possibility of contaminating the contacting portion of the lead by the solder, thereby ensuring an electrical connection between the contacting portion and the complementary element.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical connector comprising:
an insulative housing defining a mating face, a mounting face and a plurality of passageways extending through the mating face and the mounting face;
a plurality of leads being received in the passageways of the insulative housing, each lead comprising a contacting portion exposed to the mating face and a solder portion connected to the contacting portion and exposed to the mounting face; and
a discrete mass of solder being riveted to the solder portion of each lead and extending beyond the mounting face of the insulative housing.

2. The electrical connector as claimed in claim 1, wherein the solder portion of each lead is formed with a hole extending therethrough and the discrete mass of solder is partially secured by the hole of the solder portion.

3. The electrical connector as claimed in claim 1, wherein the contacting portion comprises a pair of opposite beams connected with the solder portion.

4. The electrical connector as claimed in claim 1, wherein a mass of flux is added to the discrete mass of solder.

5. The electrical connector as claimed in claim 1, wherein the solder portion defines a hole extending therethrough to partially receive the discrete mass of solder therethrough and a channel in a periphery of the hole to expose the hole outwardly.

6. A method of producing a solder-bearing lead for soldering to a conductive pad of a circuit device, comprising the steps of:
providing a lead comprising a contacting portion and a solder portion connected with the contacting portion;
providing a hole in the solder portion of the lead;
inserting a discrete mass of solder through the hole of the solder portion; and
riveting the solder on the solder portion.

7. The method as claimed in claim 6 further comprising a step of providing a channel on the solder portion to expose the hole of the solder portion outwardly.

8. The method as claimed in claim 6 further comprising a step of providing a pair of opposite beams on the contacting portion to connect to a periphery of the hole of the solder portion.

9. The method as claimed in claim 6, wherein a mass of flux is added to the discrete mass of solder.

10. A solder-bearing lead comprising:
a lead comprising a contacting portion and a solder portion perpendicularly connected to the contacting portion and defining a hole extending therethrough; and
a solder being inserted through the hole and being rivetedly secured to the solder portion.

11. The lead as claimed in claim 10, wherein the riveted solder defines a semi-spherical configuration under the solder portion.

12. The lead as claimed in claim 10, wherein a flux is associated integrally with said solder before said solder has been riveted.
